(19) United States
(12) Patent Application Publication
(10) Pub. No.: US 2021/0068291 A1
(43) Pub. Date: Mar. 4, 2021

(54) ELECTRICAL APPARATUS AND CASING APPARATUS AND A REMOVABLE PANEL MODULE THEREOF

(71) Applicant: Wistron Corporation, New Taipei City (TW)

(72) Inventor: Ho-Hsin Chen, New Taipei City (TW)

(21) Appl. No.: 16/681,728

(22) Filed: Nov. 12, 2019

(30) Foreign Application Priority Data
Aug. 26, 2019 (TW) 108130472

(51) Int. Cl. H05K 7/14; H05K 5/02

(52) U.S. Cl. CPC H05K 7/1427; H05K 7/1487; H05K 5/0239

(57) ABSTRACT

A removable panel module, separably connecting a host casing, includes a panel; a rod capable of sliding with respect to the panel, the rod having a first end and a second end; a press module disposed at the first end of the rod, the press module including a first locking element fastened to the rod and separably connecting the host casing at the first end; and an operating module disposed at the second end of the rod, the operating module including a second locking element slidingly disposed at the panel and separably connecting the host casing at the second end. When the press module is activated, the first locking element and the second locking element move in opposite directions to separate the panel from the host casing.

### CROSS-REFERENCE TO RELATED APPLICATIONS

This application claims priority to Taiwan Patent Application No. 108130472, filed on Aug. 26, 2019, the entire contents of which are herein expressly incorporated by reference.

### BACKGROUND OF THE INVENTION

### 1. Field of the Invention

The present invention generally relates to a removable panel module, and more particularly to a removable panel module adaptable to an electrical apparatus.

### 2. Description of Related Art

A server having a powerful computation capability can provide services for clients. The server may include several hard disks that are adaptable to different applications, and may be withdrawn or inserted for maintenance. The panel of the server may be made removable to facilitate withdrawing or inserting the hard disks from inside of a server casing.

The removable panel of the conventional server is commonly fastened to the server casing by screws. When removing the panel, a tool such as a screwdriver need be used to perform disassemble operation, which ordinarily takes a lot of time and effort. Moreover, the conventional server with removable panel lacks information security capability to prevent unauthorized personnel from obtaining devices (e.g., hard disks) in the server.

A need has thus arisen to propose a novel scheme to improve the removable panel of the conventional server and to protect information security of the server.

### SUMMARY OF THE INVENTION

In view of the foregoing, it is an object of the embodiment of the present invention to provide a removable panel module for removing a panel with one hand but not using any tool.

According to one embodiment, a removable panel module, separably connecting a host casing, includes a panel, a rod, a press module and an operating module. The rod is capable of sliding with respect to the panel, and has a first end and a second end. The press module is disposed at the first end of the rod, and includes a first locking element fastened to the rod and separably connecting the host casing at the first end. The operating module is disposed at the second end of the rod, and includes a second locking element slidingly disposed at the panel and separably connecting the host casing at the second end. When the press module is activated, the first locking element and the second locking element move in opposite directions to separate the panel from the host casing.

### BRIEF DESCRIPTION OF THE DRAWINGS

FIG. 1A shows a front perspective view illustrating a removable panel module according to one embodiment of the present invention;

FIG. 1B shows a rear exploded view illustrating the removable panel module of FIG. 1A;

FIG. 1C shows a perspective view exemplifying the host casing of an electrical apparatus;

FIG. 2A shows a partial perspective view illustrating the press module according to the embodiment of the present invention;

FIG. 2B shows a partial side view illustrating the press module;

FIG. 2C shows a partial top view illustrating the press module according to another embodiment of the present invention;

FIG. 3A shows a partial perspective view illustrating the operating module according to the embodiment of the present invention;

FIG. 3B shows a partial side view illustrating the operating module;

FIG. 4A shows a partial perspective view illustrating the latch module according to the embodiment of the present invention; and

FIG. 4B shows a partial side view illustrating the stopper of the latch module and the rod.

### DETAILED DESCRIPTION OF THE INVENTION

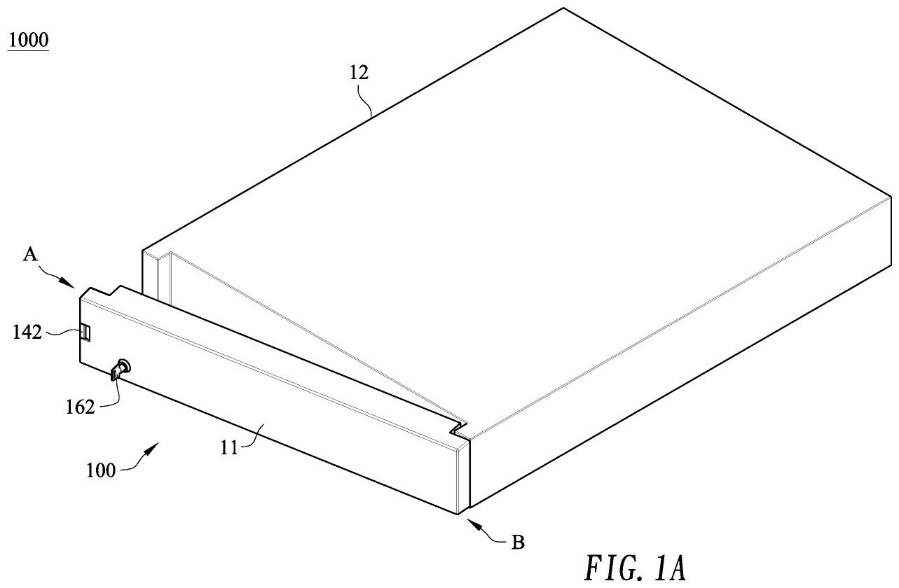

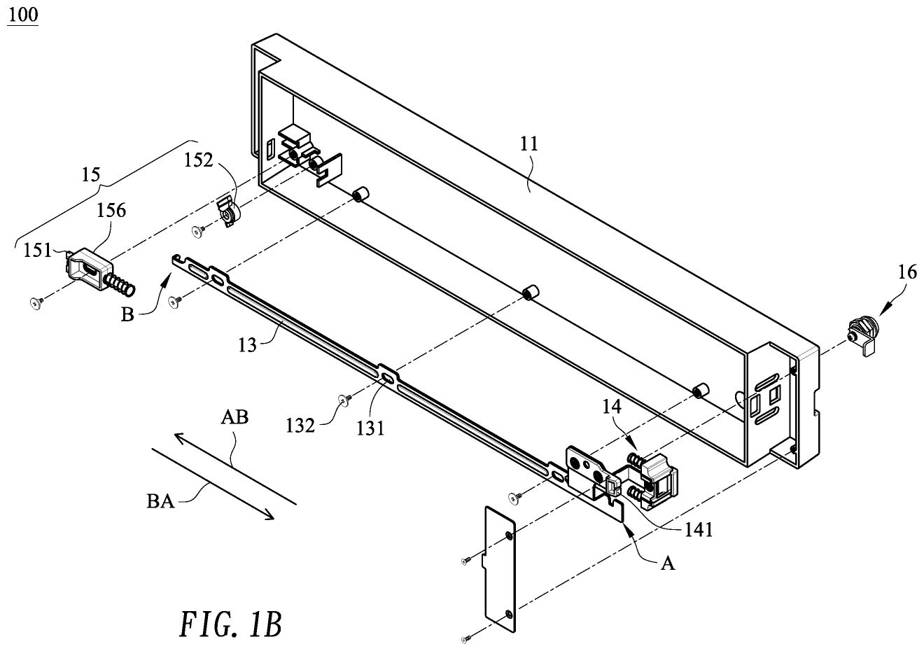

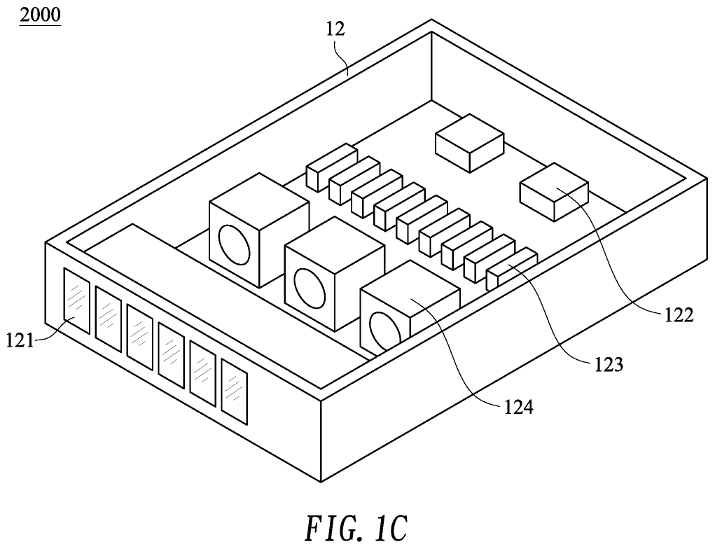

FIG. 1A shows a front perspective view illustrating a removable panel module 100, separably connecting a host casing 12, according to one embodiment of the present invention capable of being combined with the host casing 12 to result in a casing apparatus 1000. FIG. 1B shows a rear exploded view illustrating the removable panel module 100 of FIG. 1A. In one embodiment, electrical components may be disposed in the host casing 12 and be combined with the removable panel module 100 to result in an electrical apparatus such as a server. FIG. 1C shows a perspective view exemplifying the host casing 12 of an electrical apparatus 2000 having electrical or electromechanical components such as hard disks 121, processors 122, memory devices 123 and fans 124.

In the embodiment, the removable panel module 100 may primarily include a panel 11, a rod 13, a press module 14 and an operating module 15. In the embodiment, the rod 13 may have openings 131, through which screws 132 respectively pass and fasten to the panel 11. As the openings 131 have a size greater than a size of the screws 132, the rod 13 may slide with respect to the panel 11 along a longitudinal direction, for example, a horizontal direction. In one embodiment, a guiding block (not shown) surrounding the rod 13 may be disposed on the panel 11 to prevent the rod 13 from moving in an unintended direction. In another embodiment, the panel 11 may have a groove (not shown) corresponding to the rod 13 to guide the rod 13 in an intended direction.

The press module 14 disposed at a first end A of the rod 13 (or the panel 11) may include a first locking element 141 fastened to the rod 13 and separably connecting the host casing 12 at the first end A. The operating module 15 disposed at a second end B of the rod 13 (or the panel 11) may include a second locking element 151 slidingly disposed at the panel 11 and separably connecting the host casing 12 at the second end B. In the specification, a first direction AB is defined as a direction from the first end A toward the second end B, and a second direction BA is defined as a direction from the second end B toward the first end A, wherein the first direction AB is opposite the second direction BA. When the press module 14 is activated, the first locking element 141 may be released and move in the first direction AB to separate the panel 11 from the host casing 12 at the first end A. At the same time, the rod 13 moving in the first direction AB may drive the operating module 15 to release the second locking element 151, which may move in the second direction BA to separate the panel 11 from the host casing 12 at the second end B. In other words, when the press module 14 is activated, the first locking element 141 and the second locking element 151 may move in opposite directions to separate the panel 11 from the host casing 12. Accordingly, the first locking element 141 and the second locking element 151 may be released simultaneously to wholly remove the panel 11 from the host casing 12 by merely activating the press module 14 with one hand but not using any tool.

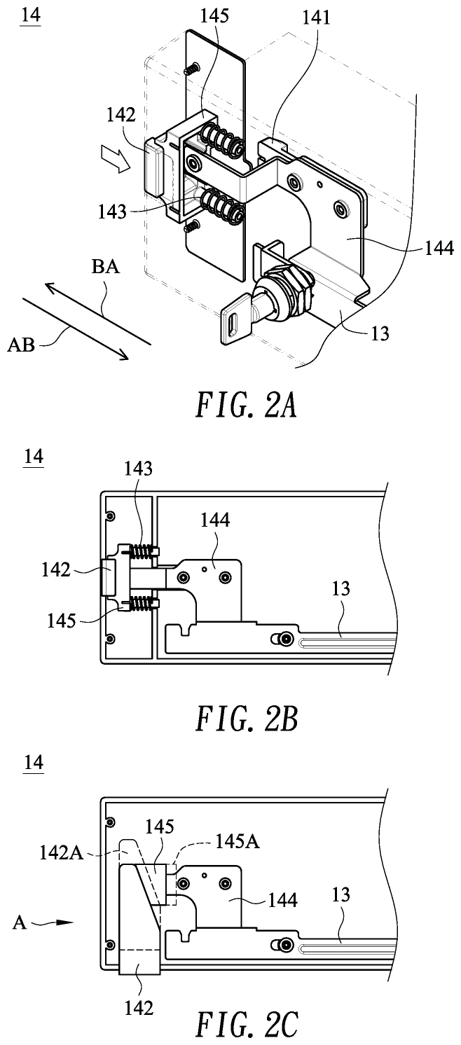

FIG. 2A shows a partial perspective view illustrating the press module 14 according to the embodiment of the present invention, and FIG. 2B shows a partial side view illustrating the press module 14. In the embodiment, the press module 14 may include a press part 142 disposed on (for example, a side surface of) the panel 11. The press module 14 may include at least one first elastic element 143, such as a spring, connected to the press part 142 at one end of the press module 14 and fastened to the panel 11 at another end of the press module 14. When the press part 142 is released, the first elastic element 143 may force the first locking element 141 and the press part 142 to move in the second direction BA until an original position has been reached. When the press part 142 is activated, the first elastic element 143 may push the rod 13 to slide in the first direction AB. At this moment, the first locking element 141 fastened to the rod 13 may move away from the host casing 12 to separate the panel 11 from the host casing 12 at the first end A.

In the embodiment, a link element 144 may be further included to connect the first end A of the rod 13 at one end of the link element 144 and connect the press part 142 and the first locking element 141 at another end of the link element 144. The link element 144 may act as an interface between the rod 13 and the press part 142 to raise distance and orientation between the rod 13 and the press part 142.

The press module 14 of the embodiment may include a pushing block 145 disposed between the press part 142 and the link element 144. When the press part 142 is activated, the pushing block 145 may indirectly push the rod 13 to slide in the first direction AB.

In the embodiment, the press part 142 may be disposed on the side surface of the panel 11 as shown in FIG. 1A and FIG. 2A. When the press part 142 is pressed in the first direction AB as indicated by the arrow depicted in FIG. 2A, the rod 13 may be pushed to slide in the first direction AB. Alternatively, the press part 142 may be disposed on other surface (e.g., a front surface) of the panel 11 instead. FIG. 2C shows a partial top view illustrating the press module 14 according to another embodiment of the present invention, in which the press part 142 may be disposed on the front surface of the panel 11. When the press part 142 is pressed toward the panel 11, the press part 142 may reach a position 142A. At this moment, the pushing block 145 may be pushed by a side surface of the press part 142 to reach a position 145A, and the rod 13 may thus slide in the first direction AB.

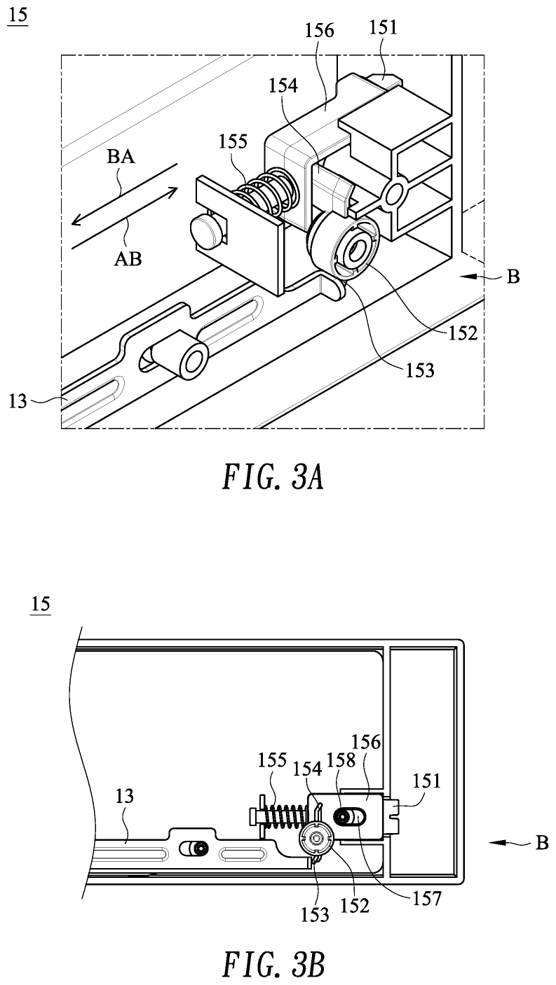

FIG. 3A shows a partial perspective view illustrating the operating module 15 according to the embodiment of the present invention, and FIG. 3B shows a partial side view illustrating the operating module 15. In the embodiment, the operating module 15 may include a rotation moving element 152 pivotally disposed at the panel 11 and capable of rotating. Although the rotation moving element 152 of the embodiment is ring-shaped, it is appreciated that the rotation moving element 152 may have other shape. The rotation moving element 152 may have a first extension part 153 disposed at one end of the first extension part 153 and connecting the second end B of the rod 13. The rotation moving element 152 may have a second extension part 154 disposed at another end of the first extension part 153 and connecting the second locking element 151. When the rod 13 slides in the first direction AB, the second end B of the rod 13 may push the first extension part 153 to move in the first direction AB, and the rotation moving part 152 may rotate and drive the second extension part 154, which may then push the second locking element 151 to move in the second direction BA and away from the host casing 12 to separate the panel 11 from the host casing 12 at the second end B.

The operating module 15 may include at least one second elastic element 155, such as a spring, connected to the second locking element 151 at one end of the second elastic element 155 and fastened to the panel 11 at another end of the second elastic element 155. When the rod 13 slides in the second direction BA to release the first extension part 153, the second elastic element 155 may push the second extension part 154 to move in the first direction AB and may drive the first extension part 153 to move in the second direction BA to force the second locking element 151 to move in the first direction AB until an original position has been reached.

In the embodiment, a linear moving element 156 may be further included to be slidingly disposed at the panel 11 and be positioned between the second locking element 151 and the second elastic element 155. In the embodiment, the linear moving element 156 may have an opening 157, through which a screw 158 passes and fasten to the panel 11. As the opening 157 has a size greater than a size of the screw 158, the linear moving element 156 may slide with respect to the panel 11 along a longitudinal direction, for example, a horizontal direction. Further, the second extension part 154 may connect the linear moving element 156 at the end that is near the second elastic element 155. When the rod 13 slides in the first direction AB, the rotation moving element 152 may rotate to drive the second extension part 154, which may push the linear moving element 156 to slide in the second direction BA to convert rotation movement to linear movement.

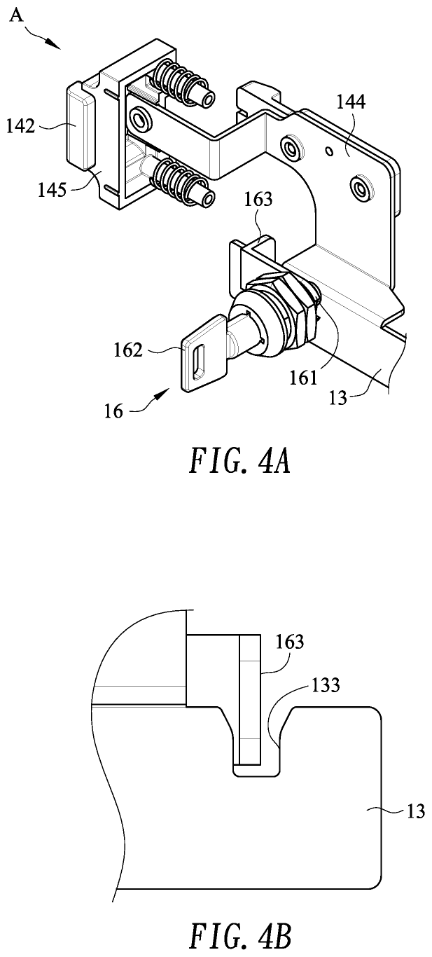

As shown in FIG. 1B, the removable panel module 100 may include a latch module 16 configured to restrict slide of the rod 13. FIG. 4A shows a partial perspective view illustrating the latch module 16 according to the embodiment of the present invention. In the embodiment, the latch module 16 may include a rotary column 161, which may be rotated by a key 162 inserted thereinto. The latch module 16 of the embodiment may include a stopper 163 fastened to the rotary column 161. FIG. 4B shows a partial side view illustrating the stopper 163 of the latch module 16 and the rod 13. When the rotary column 161 is rotated to drive the stopper 163, a front end of the stopper 163 may fall into a stop groove 133 of the rod 13 (as shown in FIG. 4B) to lock the rod 13 and to prevent the rod 13 from sliding. When the key 162 rotates the rotary column 161 again to drive the front end of the stopper 163 away from the stop groove 133 of the rod 13, the rod 13 may then be unlocked and may freely slide.

Although specific embodiments have been illustrated and described, it will be appreciated by those skilled in the art that various modifications may be made without departing from the scope of the present invention, which is intended to be limited solely by the appended claims.

What is claimed is:

1. A removable panel module, separably connecting a host casing, the removable panel module comprising:
a panel;
a rod capable of sliding with respect to the panel, the rod having a first end and a second end;
a press module disposed at the first end of the rod, the press module including a first locking element fastened to the rod and separably connecting the host casing at the first end; and
an operating module disposed at the second end of the rod, the operating module including a second locking element slidingly disposed at the panel and separably connecting the host casing at the second end;
wherein when the press module is activated, the first locking element and the second locking element move in opposite directions to separate the panel from the host casing.

2. The removable panel module of claim 1, wherein the press module comprises:
a press part; and
at least one first elastic element connected to the press part at one end of the at least one first elastic element and fastened to the panel at another end of the at least one first elastic element;
wherein the first elastic element pushes the rod to slide in a first direction when the press part is activated, and the first elastic element forces the first locking element and the press part to move in a second direction when the press part is released;
wherein the first direction is opposite the second direction.

3. The removable panel module of claim 2, further comprising:
a link element connected the first end of the rod at one end of the link element and connected the press part and the first locking element at another end of the link element.

4. The removable panel module of claim 3, wherein the press module further comprises:
a pushing block disposed between the press part and the link element, the pushing block pushing the rod when the press part is activated.

5. The removable panel module of claim 1, wherein the operating module comprises:
a rotation moving element pivotally disposed at the panel and capable of rotating;
a first extension part disposed at one end of the rotation moving element and connecting the second end of the rod; and
a second extension part disposed at another end of the rotation moving element and connecting the second locking element;
wherein when the rod slides, the second end of the rod pushes the first extension part, the rotation moving part rotates and drives the second extension part, which then pushes the second locking element.

6. The removable panel module of claim 5, wherein the operating module further comprises:
at least one second elastic element connected to the second locking element at one end of the at least one second elastic element and fastened to the panel at another end of the at least one second elastic element;
wherein when the rod slides in a second direction to release the first extension part, the second elastic element pushes the second extension part to move in a first direction and drives the first extension part to move in the second direction to force the second locking element to move in the first direction;
wherein the first direction is opposite the second direction.

7. The removable panel module of claim 6, wherein the operating module further comprises:
a linear moving element disposed between the second locking element and the second elastic element;
wherein the second extension part connects the linear moving element at an end that is near the second elastic element, and the rotation moving element rotates to drive the second extension part, which pushes the linear moving element to slide when the rod slides.

8. The removable panel module of claim 1, further comprising a latch module for restricting slide of the rod, the latch module comprises:
a rotary column that is rotated by a key inserted thereinto; and
a stopper fastened to the rotary column;
wherein when the rotary column is rotated to drive the stopper, a front end of the stopper falls into a stop groove of the rod to prevent the rod from sliding; when the key rotates the rotary column to drive the front end of the stopper away from the stop groove of the rod, the rod is allowed to slide.

9. An electrical apparatus, comprising:
a host casing;
a plurality of electrical components disposed in the host casing;
a panel connecting the host casing;
a rod capable of sliding with respect to the panel, the rod having a first end and a second end;
a press module disposed at the first end of the rod, the press module including a first locking element fastened to the rod and separably connecting the host casing at the first end; and
an operating module disposed at the second end of the rod, the operating module including a second locking element slidingly disposed at the panel and separably connecting the host casing at the second end;
wherein when the press module is activated, the first locking element and the second locking element move in opposite directions to separate the panel from the host casing.

10. The electrical apparatus of claim 9, wherein the press module comprises:
a press part; and
at least one first elastic element connected to the press part at one end of the at least one first elastic element and fastened to the panel at another end of the at least one first elastic element;
wherein the first elastic element pushes the rod to slide in a first direction when the press part is activated, and the first elastic element forces the first locking element and the press part to move in a second direction when the press part is released;
wherein the first direction is opposite the second direction.

11. The electrical apparatus of claim 10, further comprising:
a link element connected the first end of the rod at one end of the link element and connected the press part and the first locking element at another end of the link element.

12. The electrical apparatus of claim 11, wherein the press module further comprises:
a pushing block disposed between the press part and the link element, the pushing block pushing the rod when the press part is activated.

13. The electrical apparatus of claim 9, wherein the operating module comprises:
a rotation moving element pivotally disposed at the panel and capable of rotating;
a first extension part disposed at one end of the rotation moving element and connecting the second end of the rod; and
a second extension part disposed at another end of the rotation moving element and connecting the second locking element;
wherein when the rod slides, the second end of the rod pushes the first extension part, the rotation moving part rotates and drives the second extension part, which then pushes the second locking element.

14. The electrical apparatus of claim 13, wherein the operating module further comprises:
at least one second elastic element connected to the second locking element at one end of the at least one second elastic element and fastened to the panel at another end of the at least one second elastic element;
wherein when the rod slides in a second direction to release the first extension part, the second elastic element pushes the second extension part to move in a first direction and drives the first extension part to move in the second direction to force the second locking element to move in the first direction;
wherein the first direction is opposite the second direction.

15. The electrical apparatus of claim 14, wherein the operating module further comprises:
a linear moving element disposed between the second locking element and the second elastic element;
wherein the second extension part connects the linear moving element at an end that is near the second elastic element, and the rotation moving element rotates to drive the second extension part, which pushes the linear moving element to slide when the rod slides.

16. The electrical apparatus of claim 9, further comprising a latch module for restricting slide of the rod, the latch module comprises:
a rotary column that is rotated by a key inserted thereinto; and
a stopper fastened to the rotary column;
wherein when the rotary column is rotated to drive the stopper, a front end of the stopper falls into a stop groove of the rod to prevent the rod from sliding; when the key rotates the rotary column to drive the front end of the stopper away from the stop groove of the rod, the rod is allowed to slide.

17. A casing apparatus, comprising:
a host casing;
a panel connecting the host casing;
a rod capable of sliding with respect to the panel, the rod having a first end and a second end;
a press module disposed at the first end of the rod, the press module including a first locking element fastened to the rod and separably connecting the host casing at the first end; and
an operating module disposed at the second end of the rod, the operating module including a second locking element slidingly disposed at the panel and separably connecting the host casing at the second end;
wherein when the press module is activated, the first locking element and the second locking element move in opposite directions to separate the panel from the host casing.

18. The casing apparatus of claim 17, wherein the operating module comprises:
a rotation moving element pivotally disposed at the panel and capable of rotating;
a first extension part disposed at one end of the rotation moving element and connecting the second end of the rod; and
a second extension part disposed at another end of the rotation moving element and connecting the second locking element;
wherein when the rod slides, the second end of the rod pushes the first extension part, the rotation moving part rotates and drives the second extension part, which then pushes the second locking element.

19. The casing apparatus of claim 18, wherein the operating module further comprises:
a linear moving element slidingly disposed at the panel and connecting the second locking element;
wherein the second extension part connects the linear moving element, and the rotation moving element rotates to drive the second extension part, which pushes the linear moving element to slide when the rod slides.

20. The casing apparatus of claim 17, further comprising a latch module for restricting slide of the rod, the latch module comprises:
a rotary column that is rotated by a key inserted thereinto; and
a stopper fastened to the rotary column;
wherein when the rotary column is rotated to drive the stopper, a front end of the stopper falls into a stop groove of the rod to prevent the rod from sliding; when the key rotates the rotary column to drive the front end of the stopper away from the stop groove of the rod, the rod is allowed to slide.
